(19) United States
(12) Patent Application Publication
(10) Pub. No.: US 2025/0185212 A1
(43) Pub. Date: Jun. 5, 2025

(54) Modular Cooling Systems

(71) Applicant: Calaris Technologies, Woodridge, IL (US)

(72) Inventor: Rob Weber, Woodridge, IL (US)

(73) Assignee: Calaris Technologies, Woodridge, IL (US)

(21) Appl. No.: 18/967,454

(22) Filed: Dec. 3, 2024

Related U.S. Application Data
(60) Provisional application No. 63/605,708, filed on Dec. 4, 2023.

(51) Int. Cl. H05K 7/20

(52) U.S. Cl. CPC H05K 7/20327; H05K 7/20318; H05K 7/20381

(57) ABSTRACT

Described herein are examples of cooling systems comprising a frame having first and second sides with respective stackable shelving modules. The frame supports customized arrangement of compartments for optimal electronic component cooling. The system includes first and second pluralities of compartments on respective shelving modules, where compartments are slidable, closable, and removable. Each compartment connects to a common trough or channel and includes an elevation adjustment component for controlled raising and lowering. Within each compartment, a compartment houses liquid coolant and electronic components, featuring an opening to the common trough, a base grate elevating the electronic component, and interconnect components at compartment corners securing to adjacent compartments. The system provides efficient cooling through modular design and controlled liquid coolant circulation.

The present application claims the benefit of U.S. Provisional Patent Application No. 63/605,708 entitled “Modular Cooling Systems”, filed on Dec. 4, 2023. The entire contents of the above-listed application are hereby incorporated by reference for all purposes.

### BACKGROUND

In the field of thermal management, addressing the need for effective heat dissipation in various applications is vital for preserving optimal conditions in heat generating electronic components, preventing potential damage from overheating. Within this field, cooling technologies aim to meet specific challenges posed by the heat generated during electronic operations. As electronic components become more complex and compact, conventional cooling methods encounter difficulties in providing efficient and space-effective solutions. In the specialized realm of thermal management systems, the focus lies on developing innovative cooling systems to effectively dissipate heat generated by electronic components during operation. This specific field addresses the evolving challenges posed by the increasing complexity and shrinking dimensions of modern electronic components.

### BRIEF DESCRIPTION OF THE DRAWINGS

The present description will be understood more fully when viewed in conjunction with the accompanying drawings of various examples of modular cooling systems. The description is not meant to limit the modular cooling systems to the specific examples. Rather, the specific examples depicted and described are provided for explanation and understanding of modular cooling systems. Throughout the description the drawings may be referred to as drawings, figures, and/or FIGs.

FIG. 1 illustrates a perspective view of a modular cooling system, according to an embodiment;

FIG. 2 illustrates a top-down cross-sectional view of a modular cooling system, according to an embodiment;

FIG. 3 illustrates a side view of stacked modules within a frame of a modular cooling system, according to an embodiment;

FIG. 4 illustrates a perspective view of a compartment of a modular cooling system, according to an embodiment;

FIG. 5 illustrates a side view of a common channel or trough in a modular cooling system, according to an embodiment; and

FIG. 6 depicts two compartments within a modular cooling system, illustrating fluid flow and a condenser component of the cooling system in accordance with an embodiment.

### DETAILED DESCRIPTION

In the field of thermal management, a conventional setup typically comprises standard components like fans and heat sinks. These elements are designed to manage heat generated by electronic components, with fans facilitating air circulation and heat sinks dissipating heat through metal fins. The evolution of electronic components has led to increasingly complex and compact designs, creating new challenges in thermal management that traditional cooling approaches struggle to address effectively.

When examining alternative approaches, several critical limitations become apparent. Existing cooling solutions often fail to adapt to the increasing complexity and spatial constraints of modern electronic components. Traditional cooling methods rely heavily on air circulation and fixed heat sink configurations, which become less effective as component density increases. Furthermore, conventional systems typically require complex plumbing installations, increasing both cost and maintenance complexity. These limitations particularly impact scenarios requiring flexible cooling solutions for diverse electronic configurations.

Implementations of modular cooling systems address these challenges through an innovative approach to thermal management. The technology introduces a modular and stackable cooling system where individual compartments house both electronic components and liquid coolant within the same chamber. This design inherently eliminates the need for traditional plumbing while providing a versatile solution for different configurations. The inclusion of an elevation adjustment component, coupled with a controlled fluid descent triggered by compartment movement, fundamentally transforms the cooling process.

The disclosed embodiments provide a solution through several key elements. First, the stackable and modular design addresses spatial constraint challenges while maintaining adaptability to different electronic setups. Second, the use of an individual chamber in each compartment streamlines the cooling process by creating direct contact between components and coolant. Third, the elevation adjustment component and controlled fluid descent mechanism enhance system efficiency while eliminating the complexity of traditional plumbing systems. This integrated approach provides a cost-effective and adaptable solution for cooling electronic components while overcoming the limitations of conventional cooling methods.

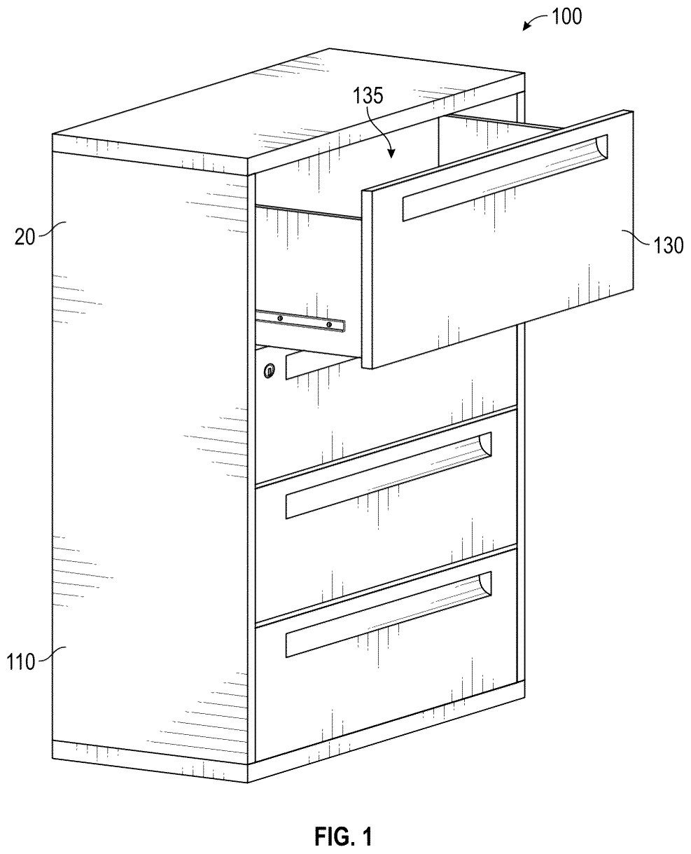

FIG. 1 illustrates a perspective view of a modular cooling system 100, according to an embodiment. The modular cooling system 100 may be configured to enable an operator to customize shelving module and compartment arrangements for optimal cooling of one or more electronic components. For the purposes of this application, an “electronic component” means a component or device that can be submerged in a liquid without compromising functionality, such as a server, a data storage unit, a computer system, a power supply unit, a networking component, a computing component, and the like. According to various embodiments, the modular cooling system 100 may comprise a frame 110 with stackable shelving modules 120, where each shelving module 120 accommodates one or more compartments 130. Each compartment 130 may comprise a chamber 135 that houses a liquid coolant and an electronic component requiring cooling, and each chamber 135 may comprise an opening (not shown) connected to a common trough or channel (not shown). The modular cooling system 100 may also comprise an elevation adjustment component (not shown) that enables an operator to selectively raise and lower each compartment 130 and control a fluid flow from the chamber to a reservoir (not shown) by gravity below the chambers 135. Additionally, the modular cooling system 100 may comprise a pump (not shown) for circulating the liquid coolant from the reservoir through a heat exchanger (not shown) and back to the chamber 135, providing a continuous flow of liquid coolant throughout the system 100.

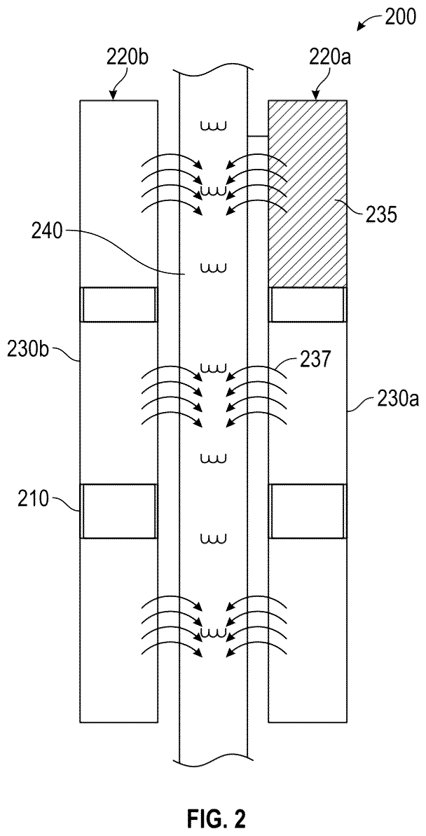

FIG. 2 illustrates a top-down cross-sectional view of a modular cooling system 200, according to an embodiment. The modular cooling system 200 may comprise a frame 210. The frame 210 may comprise various embodiments to enhance adaptability and flexibility within the system 200. In one embodiment, the frame 210 may be configured as a modular structure, allowing for the attachment of a first set of stackable shelving modules 220a on a first side of the frame 210 and a second set of stackable shelving modules 220b on a second side opposite the first side. As shown, the first set of stackable shelving modules 220a may be configured to accommodate a first plurality of compartments 230a, and the second set of stackable shelving modules 220b may be configured to accommodate a second plurality of compartments 230b. The first and second plurality of compartments 230a, 230b may be slidable open, closable, or removable from their respective modules. Each compartment 230, as part of different embodiments, may comprise a chamber 235 configured to house an electronic component that requires cooling. Each chamber 235 may be configured to hold liquid coolant and the electronic component such that the electronic component can be submerged within the liquid coolant. Additionally, each chamber 235 may comprise an opening 237 connected to a common trough or channel 240. The opening 237 may allow the liquid coolant to exit the chambers 235 and drain into a reservoir (not shown) below the chambers 235 once the liquid coolant has absorbed sufficient heat from the electronic components.

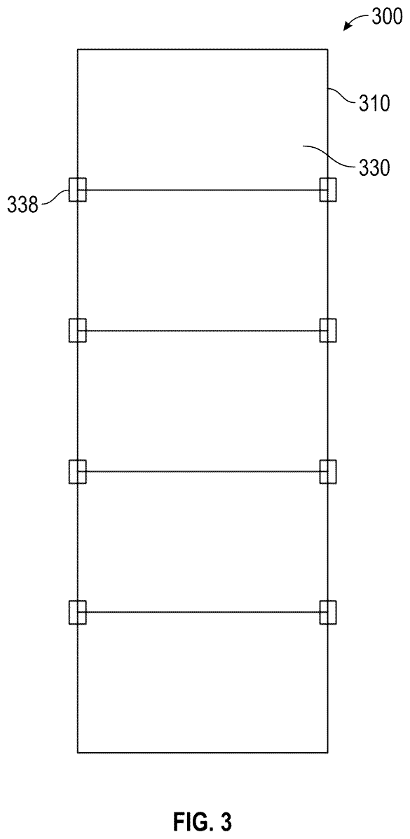

FIG. 3 illustrates a side view of stacked compartments 330 within a frame 310 of a modular cooling system 300, showing the arrangement and configuration of the compartments 330 in accordance with an embodiment. The stackability and modularity of the system 300 may allow for customization and make possible for an operator to configure and arrange the modular cooling system 300 to suit specific spatial constraints and cooling requirements efficiently. In this embodiment, each compartment 330 may comprise one or more interconnect components 338, comprising complementary features on the frame 310, such as tabs or notches, that securely connect with corresponding recesses on adjacent compartments 330. The interconnect components 338 may be positioned at all four corners of each compartment 330. By having interconnect components 338 at each corner, the compartments 330 may securely attach to the frame 310 or one another and form an integrated structure that is stable and prevents unintended movement when the compartments 330 are stacked. Moreover, the interconnect components 338 allow for straightforward assembly and disassembly of the stacked compartments 330 without the need for additional tools.

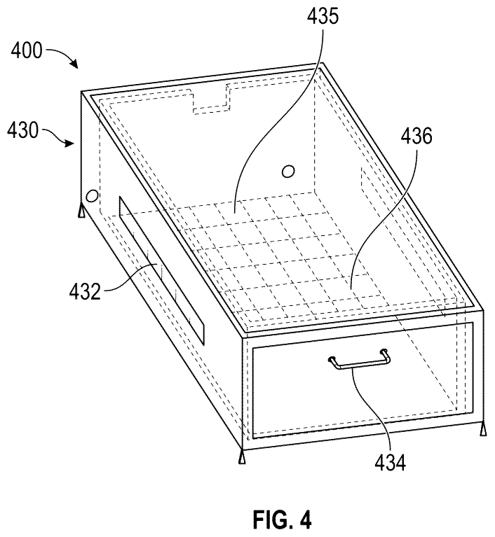

FIG. 4 illustrates a perspective view of a compartment 430 of a modular cooling system 400, according to an embodiment. The compartment 430 may comprise a slide rail 432 that is connected to a wheel or another component (not shown) of a frame (not shown). This connection may allow the compartment 430 to glide with ease along the slide rail 432 to provide how an operator to open and close the compartment 430. The compartment 430 may comprise a handle 434 to make possible for an operator to easily open, close, or remove the compartment 430 from a shelving module (not shown) of the system 400. This may allow an operator to quickly and conveniently access a chamber 435 of the compartment 430 to perform maintenance or retrieve contents. Moreover, the compartment 430 may comprise a grate 436 positioned at a base or lower surface of the compartment 430. The grate 436 may be positioned underneath an electronic component where the electronic component rests on the grate 436 and is elevated above the base or lower surface of the compartment 430 to allow liquid coolant that is returned to the compartment 430 to efficiently access the bottom of the electronic component and make direct contact with its lower surfaces. As the liquid coolant circulates within the chamber 435, it absorbs heat generated by the electronic component. The direct contact and heat absorption may prevent localized hotspots and may uniformly cool the electronic component within the chamber 435. In this regard, the electronic component located within the chamber 435 may receive thorough and consistent cooling, which in turn optimizes performance and longevity of the electronic component.

It will be appreciated that modifications may be made to the manner in which the chambers 435 are accessed. For instance, in an alternative embodiment, a self-contained unit with a cover (not shown) may be used instead of compartments. The cover can be opened or closed for quick access to the electronic component or contents stored within the chamber. In another embodiment, the frame may be enclosed, and units are inserted at the back and then moved from the front to the back for access.

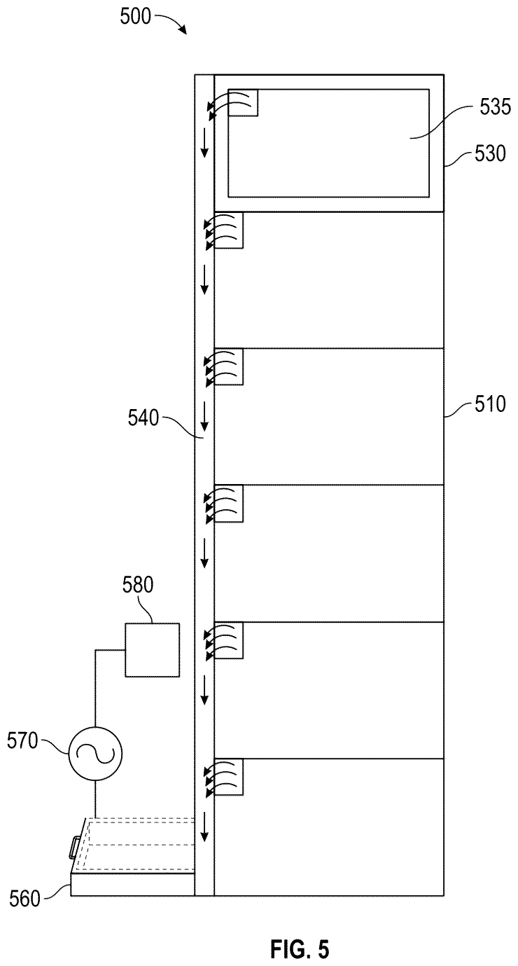

FIG. 5 illustrates a side view of a common channel or trough 540 in a cooling system 500, according to an embodiment. The channel or trough 540 may serve as a controlled pathway for fluid flow between compartments 530 and a reservoir 560 distally located from the compartments 530. The reservoir 560 may store liquid coolant that falls or travels through the channel or trough 540 from the chambers 535 after the liquid coolant absorbs and transports heat away from components. The cooling system 500 may comprise an elevation adjustment component (not shown), allowing an operator to selectively raise and lower each compartment 530 with respect to a frame 510 of the system. This component may operate with the opening and closing of the compartments 530, triggering a controlled fluid descent action where the liquid coolant sequentially descends from one compartment to the next. For instance, when a compartment 530 is opened, the elevation adjustment component activates, leading to a controlled descent of liquid coolant from the top chamber 535 to the chamber below and so forth and then into the reservoir 560. The elevation adjustment component allows for secure integration and controlled vertical movement of the compartments 530 within the system 500. The resulting controlled descent of the liquid coolant may create a cascading effect similar to a waterfall and provides an efficient transfer of liquid coolant from the chambers 535 to the reservoir 560.

The elevation adjustment component may be integrated into the frame 510 or structure of the modular cooling system 500. It may be attached using mounting brackets, fasteners, or other suitable connectors. The elevation adjustment component may comprise a hydraulic lift, a pneumatic system, a mechanical jack, or any other component or system capable of selectively raising and lowering each compartment 530 within the modular cooling system 500.

Modifications can be made to how the liquid coolant is collected or sent to the reservoir 560 without altering the technology's scope. In an alternative embodiment, the liquid coolant may flow through a flexible tube (not shown) connected to the common trough or channel 540, which incorporates a cover or a device capable of blocking the opening of the chamber. This device can be manually or automatically closed, thereby eliminating the need to adjust the elevation of the compartments 530 for draining the chambers 535 of liquid coolant. In yet another embodiment, the liquid coolant may flow directly into the reservoir 560 through a flexible tube connected to the chamber 535, bypassing the common trough or channel. This configuration allows the liquid coolant to flow directly from each chamber 535 to the reservoir 560.

A pump 570 fluidly coupled to the reservoir 560 may be configured to extract the liquid coolant from the reservoir 560, which accumulates from the chambers 535, and pump or direct it through a heat exchanger 580. In the heat exchanger 580, the liquid coolant undergoes a cooling process, dissipating the heat absorbed from the electronic components housed in the chambers 535. Subsequently, the liquid coolant circulates back into the system through water pump intake tubes (not shown), extending into each individual chamber 535 and connecting the reservoir 560 to the chambers 535. As the liquid coolant fills each chamber 535, it absorbs heat from the electronic components until the liquid coolant heats up, and the cycle continues. This embodiment may provide a continuous cycle that sustains optimal cooling conditions. Consequently, the modular cooling system 500 may maintain a stable and controlled temperature environment for the electronic components, which may in turn ensure their reliable operation and longevity.

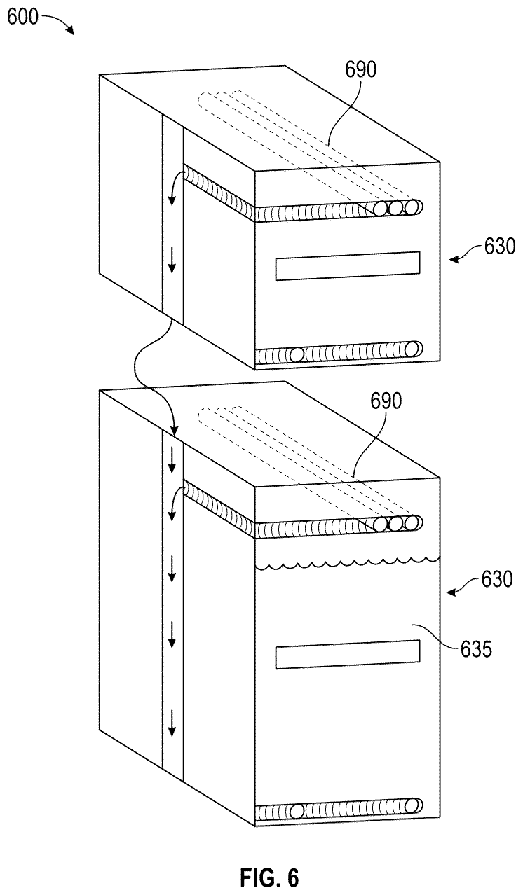

FIG. 6 depicts two compartments 630 within a cooling system 600, illustrating fluid flow and condenser components 690 in accordance with an embodiment. The condenser components 690 may contribute to the efficiency of the cooling system 600 by effectively managing the thermal exchange process and maintaining a conducive environment for the electronics within chambers 635 of the compartments 630. For instance, once a liquid coolant is drawn from a reservoir (not shown) of the system 600 and directed through a heat exchanger (not shown), it enters the condenser components 690. The condenser components 690 may facilitate the transfer of heat from the liquid coolant to the surrounding environment. As the liquid coolant circulates through the heat exchanger 690, it releases thermal energy to the surrounding environment, causing the liquid coolant to cool down. This step may ensure that the liquid coolant returns to the chambers 635 at a lower temperature and ready to absorb more heat from the electronic components. In an embodiment, the condenser components 690 may include a two phase setup. In another embodiment, the condenser components 690 may include a heat pipe or tube where cooler fluid moves through the heat pipe and surrounding warmer fluid transfers heat into the heat pipe or tube.

The condenser components 690 in the modular cooling system 600 may be integrated within the compartments 630 or placed in other suitable locations. The flexibility of the condenser components 690 in terms of their placement allows for efficient heat dissipation in close proximity to the electronic components housed in each chamber 635. Integrating the condenser components 690 within the compartments ensures a compact and streamlined design and optimizes spatial utilization. Alternatively, situating the condenser components 690 elsewhere may offer advantages in terms of system configuration and maintenance.

In an alternate embodiment, the modular cooling system 600 may further comprise various energy capture technologies, utilizing them for enhanced energy capture, analogous to the principle observed in larger structures yielding increased energy, such as taller dam structures. For instance, in data center applications, the cooling system 600 may employ the energy capture technologies to harness the cascading effect generated through the stacking of the compartments or units and capture energy more effectively. This harnessed energy may then power pumps or other system components to provide efficient fluid circulation and cooling.

A feature illustrated in one of the figures may be the same as or similar to a feature illustrated in another of the figures. Similarly, a feature described in connection with one of the figures may be the same as or similar to a feature described in connection with another of the figures. The same or similar features may be noted by the same or similar reference characters unless expressly described otherwise. Additionally, the description of a particular figure may refer to a feature not shown in the particular figure. The feature may be illustrated in and/or further described in connection with another figure.

Elements of processes (i.e. methods) described herein may be executed in one or more ways such as by a human, by a processing device, by mechanisms operating automatically or under human control, and so forth. Additionally, although various elements of a process may be depicted in the figures in a particular order, the elements of the process may be performed in one or more different orders without departing from the substance and spirit of the disclosure herein.

The preceding description sets forth numerous details such as examples of specific systems, components, methods, and so forth, to provide a good understanding of several implementations. However, it will be apparent to one skilled in the art that at least some implementations may be practiced without these specific details. In other instances, well-known components or methods are not described in detail or are presented in simple block diagram format to avoid unnecessarily obscuring the present implementations. Thus, the specific details set forth above are merely exemplary. Particular implementations may vary from these exemplary details and still be within the scope of the present implementations.

Related elements in the examples and/or embodiments described herein may be identical, similar, or dissimilar in different examples. For the sake of brevity and clarity, related elements may not be redundantly explained. Instead, the use of a same, similar, and/or related element names and/or reference characters may cue the reader that an element with a given name and/or associated reference character may be similar to another related element with the same, similar, and/or related element name and/or reference character in an example explained elsewhere herein. Elements specific to a given example may be described regarding that particular example. A person having ordinary skill in the art will understand that a given element need not be the same and/or similar to the specific portrayal of a related element in any given figure or example in order to share features of the related element.

It is to be understood that the foregoing description is intended to be illustrative and not restrictive. Many other implementations will be apparent to those of skill in the art upon reading and understanding the above description. The scope of the present implementations should, therefore, be determined with reference to the appended claims, along with the full scope of equivalents to which such claims are entitled.

The foregoing disclosure encompasses multiple distinct examples with independent utility. While these examples have been disclosed in a particular form, the specific examples disclosed and illustrated above are not to be considered in a limiting sense as numerous variations are possible. The subject matter disclosed herein includes novel and non-obvious combinations and sub-combinations of the various elements, features, functions and/or properties disclosed above both explicitly and inherently. Where the disclosure or subsequently filed claims recite “a” element, “a first” element, or any such equivalent term, the disclosure or claims is to be understood to incorporate one or more such elements, neither requiring nor excluding two or more of such elements.

As used herein “same” means sharing all features and “similar” means sharing a substantial number of features or sharing materially important features even if a substantial number of features are not shared. As used herein “may” should be interpreted in a permissive sense and should not be interpreted in an indefinite sense. Additionally, use of “is” regarding examples, elements, and/or features should be interpreted to be definite only regarding a specific example and should not be interpreted as definite regarding every example. Furthermore, references to “the disclosure” and/or “this disclosure” refer to the entirety of the writings of this document and the entirety of the accompanying illustrations, which extends to all the writings of each subsection of this document, including the Title, Background, Brief description of the Drawings, Detailed Description, Claims, Abstract, and any other document and/or resource incorporated herein by reference.

As used herein regarding a list, “and” forms a group inclusive of all the listed elements. For example, an example described as including A, B, C, and D is an example that includes A, includes B, includes C, and also includes D. As used herein regarding a list, “or” forms a list of elements, any of which may be included. For example, an example described as including A, B, C, or D is an example that includes any of the elements A, B, C, and D. Unless otherwise stated, an example including a list of alternatively-inclusive elements does not preclude other examples that include various combinations of some or all of the alternatively-inclusive elements. An example described using a list of alternatively-inclusive elements includes at least one element of the listed elements. However, an example described using a list of alternatively-inclusive elements does not preclude another example that includes all of the listed elements. And, an example described using a list of alternatively-inclusive elements does not preclude another example that includes a combination of some of the listed elements. As used herein regarding a list, “and/or” forms a list of elements inclusive alone or in any combination. For example, an example described as including A, B, C, and/or D is an example that may include: A alone; A and B; A, B and C; A, B, C, and D; and so forth. The bounds of an “and/or” list are defined by the complete set of combinations and permutations for the list.

Where multiples of a particular element are shown in a FIG., and where it is clear that the element is duplicated throughout the FIG., only one label may be provided for the element, despite multiple instances of the element being present in the FIG. Accordingly, other instances in the FIG. of the element having identical or similar structure and/or function may not have been redundantly labeled. A person having ordinary skill in the art will recognize based on the disclosure herein redundant and/or duplicated elements of the same FIG. Despite this, redundant labeling may be included where helpful in clarifying the structure of the depicted examples.

The Applicant(s) reserves the right to submit claims directed to combinations and sub-combinations of the disclosed examples that are believed to be novel and non-obvious. Examples embodied in other combinations and sub-combinations of features, functions, elements and/or properties may be claimed through amendment of those claims or presentation of new claims in the present application or in a related application. Such amended or new claims, whether they are directed to the same example or a different example and whether they are different, broader, narrower or equal in scope to the original claims, are to be considered within the subject matter of the examples described herein.

1. A system, comprising:
a modular shelving frame comprising:
a first side and a second side, separated by a channel, wherein the first side and second side comprise:
a first stackable shelving module removably positioned on the first side;
a second stackable shelving module removably positioned on the second side; and
a compartment:
integrated into the first stackable shelving module and the second stackable shelving module; and
positioned within the first stackable shelving module and the second stackable shelving module to cool an electronic components, wherein
the compartment integrated into the first stackable shelving module and the second stackable shelving module comprising:
an openable panel, a closable panel, or a removable panel;
a grate, upon which to rest electronic equipment; and
connected with independently connected fluid pathways with the channel;
wherein the channel:
is connected with a fluid pathway to a coolant reservoir; and further comprises:
a fluid pump intake tube extending into the compartment;
an opening at the compartment interface;
a reservoir positioned below the compartment; and
an external pump;
an elevation adjustment component configured to raise and lower the first stackable shelving module and the second stackable shelving module.

2. The system of claim 1, wherein the channel:
is disposed inside of the frame structure, between the first stackable shelving module and the second stackable shelving module;
is formed to channel gravity-assisted fluid flow; and wherein
the common trough or channel further comprises a series of vertically offset collection points corresponding to the compartment opening and terminating at the reservoir.

3. The system of claim 1, wherein the channel:
is connected with fluid pathways to a coolant reservoir;
is in connected with fluid pathways to an external pump; and
wherein the fluid pathways further comprise:
a water pump intake tube extending into the compartment;
an opening at the compartment interface; and
and a reservoir positioned below the compartments.

4. The system of claim 3, wherein the channel distributes coolant through the frame by an extraction phase, a distribution phase, and on a continuous cycle.

5. The system of claim 1, wherein
the first stackable shelve module or the second stackable shelve module further comprises a tab or notch formed in a corner of the compartment, wherein the tab or notch further comprise:
a corresponding surface that securely connect to the frame;
a corresponding recess on an adjacent compartment; and
an interconnect component positioned at a first corner or a second corner of the compartment.

6. The system of claim 1, wherein the compartment is configured to hold: a server, a data storage unit, a computer system, a power supply unit, a networking component, a computing component, a graphics processing array, a memory bank assembly, a data processing unit, or telecommunications equipment.

7. The system of claim 1, wherein the elevation adjustment component comprises:
a hydraulic lift, a pneumatic system, or a mechanical jack integrated into the frame with removably mounted fasteners, wherein the elevation adjustment component further comprises:
a vertical displacement mechanism;
a descent control assembly;
a movement stabilization structure; and
a positional control interface.

8. The system of claim 1, comprising a coolant distribution assembly that comprises:
a flexible conduit structure coupled to the channel;
a channel coupling mechanism securing the flexible conduit structure;
a flow control gate positioned within the flexible conduit structure;
an access port seal interfacing with the compartment opening; and
a fluid pathway interface between the flexible conduit structure and the compartment.

9. A method, comprising:
positioning an electronic component within a compartment of a modular cooling system;
connecting a pump to a reservoir of the modular cooling system;
circulating liquid coolant from the reservoir through a heat exchanger;
distributing the liquid coolant to the compartments through a water pump intake tube;
submerging the electronic components in the liquid coolant within the compartment;
adjusting the elevation of the compartment to facilitate controlled descent of liquid coolant, further comprising:
securing integration with the frame structure;
moving, the first stackable shelving module and the second stackable shelving module within the frame vertically;
opening a compartment to trigger the sequential descent of liquid coolant, further comprising:
vertically adjusting the compartment along the slide rail;
manipulating the elevation adjustment component to vertically move the shelving units;
circulating liquid coolant through at least one opening to the channel; and
producing in the channel cascade, comprising the steps of:
collecting heated liquid coolant in the reservoir through a channel;
cooling the collected liquid coolant through the heat exchanger; and
recirculating the cooled liquid coolant to the compartments.

10. The method of claim 9, further comprising:
determining cooling requirements of an electronic component; and
selecting compartment configurations through compartment geometry channel geometry, given the cooling requirements of an electronic component.

11. The method of claim 9, wherein the pump comprises a primary pump coupled to the reservoir and a secondary pump coupled to the water pump intake tubes, wherein the primary pump is oriented to extract the liquid coolant from the reservoir which accumulates from the compartment and pump it through the heat exchange.

12. The method of claim 9, wherein the liquid coolant descends through the channel prior to recirculation through the heat exchanger, wherein the channel comprises:
a sequential arrangement of openings corresponding to vertically stacked compartments;
an elevation-adjusted positioning relative to the compartment; and
a fluid pathway configured to direct liquid coolant to descend from the top compartment to compartments below and then into the reservoir.

13. The method of claim 9, wherein positioning electronic components comprises placing them on grates within the compartments, wherein the grate further comprises:
a perforated support platform at the compartment base;
elevation spacers between the platform and compartment floor; and
component contact surfaces maintaining vertical separation from the compartment base.

14. The method of claim 9, wherein submerging the electronic components comprises:
circulating liquid coolant within a compartment that houses the electronic component;
positioning components, in the compartment, to facilitate direct contact between the coolant and component surfaces; and
distributing the liquid coolant to create uniform cooling of the electronic component.

15. A system, comprising:
a frame configured to thermally stabilize an electronic component via controlled liquid coolant flow; wherein the frame comprises:
first and second sides, formed to receive a first stackable shelving module and a second stackable shelving module;
a channel formed to direct sequential fluid descent;
and an elevation adjustment component for controlled descent of fluid coolant along the channel;
a compartment integrated in the first stackable shelving module and the second stackable shelving module and formed to:
receive liquid coolant via circulation from the central channel;
hold electronic component on a grate positioned at the compartment base;
contain a removable panel or door to access the compartment; and
stay in fluid communication with the central channel and a reservoir through the circulation of liquid coolant;
an electrical component with a specific thermal management requirement, that undergoes the steps of:
housing, within a compartment formed in the modular shelf, circulating liquid coolant, within the compartment component;
positioning the component within the compartment, to facilitate direct contact between the coolant and component surfaces; and
distributing the liquid coolant to create uniform cooling of the electronic component.

16. The system of claim 15, wherein the electronic component comprises a server, data storage unit, computer system, power supply unit, or networking component capable of submerged operation.

17. The system of claim 16, wherein the electronic component is housed in a compartment further comprising:
an opening from where coolant can exit; and
independent, direct connection to the channel.

18. The system of claim 15, wherein:
the compartment is thermally isolated from adjacent compartments;
components undergo independent cooling control; and
the compartment includes a grate positioned to maintain coolant contact with the electronic component surfaces.

19. The system of claim 15, wherein the first stackable shelving module, the second stackable shelving module and the integrated compartment are integrated to form a unified cooling structure, wherein the integration is achieved through interconnect components positioned at compartment corners.

20. The system of claim 15, further comprising a condenser component positioned within the compartment, wherein:
the condenser component is configured to manage thermal exchange between the liquid coolant and surrounding environment; and
the condenser component may be alternatively positioned in proximity to an electronic component for optimized heat dissipation.
